(19) United States
(12) Patent Application Publication
(10) Pub. No.: US 2012/0155032 A1
(43) Pub. Date: Jun. 21, 2012

(54) SUPPORT MECHANISM AND AN ELECTRONIC DEVICE HAVING THE SAME

(75) Inventor: Shyuan-He Shih, New Taipei City (TW)

(73) Assignee: WISTRON CORPORATION, New Taipei City (TW)

(21) Appl. No.: 13/166,449

(22) Filed: Jun. 22, 2011

(30) Foreign Application Priority Data
Dec. 17, 2010 (TW) 099144497

(51) Int. Cl. H05K 7/16; F16M 11/20; H05K 7/00

(52) U.S. Cl. 361/725; 248/176.1; 248/440.1

(57) ABSTRACT

A supporting mechanism for supporting a display screen on a base includes a connecting plate, a hinged plate, and a supporting element. The connecting plate is adapted to be disposed on the display screen, and includes a first hinged element. The hinged plate is hinged to and rotatable about the first hinged element, and includes a second hinged element. The supporting element has a first end hinged to and rotatable about the second hinged element, and a second end opposite to the first end and adapted to be engageable with the base to support the display screen on the base.

### CROSS-REFERENCE TO RELATED APPLICATION

This application claims priority of Taiwanese Application No. 099144497 filed on Dec. 17, 2010.

### BACKGROUND OF THE INVENTION

1. Field of the Invention

This invention relates to a supporting mechanism, and more particularly to a supporting mechanism for supporting a display screen on a base and an electronic device having the same.

2. Description of the Related Art

A tablet computer is usually placed directly on a table for use, and cannot be adjusted to an appropriate inclination angle relative to the table to facilitate input of data or viewing of the screen. Hence, the tablet computer is very inconvenient to use.

A tablet computer and a supporting method therefor, as disclosed in Taiwanese Patent No. I301528, includes a rotating mechanism provided between a computer body and a battery device. The rotating mechanism rotates the battery device from a connecting position to a supporting position to support the computer body. However, the aforesaid patent is not provided with a stop mechanism to prevent the rotating mechanism from rotation. When a user applies a larger force on a button, the rotating mechanism is easily rotated, thereby moving the battery device from the supporting position to the connecting position. Thus, the battery device cannot be stably positioned on the supporting position. Further, because the battery device can only be rotated to the supporting position at a specific angle, it cannot satisfy a user's requirement to rotate the computer body to a selected angular position.

### SUMMARY OF THE INVENTION

A main object of the present invention is to provide a supporting mechanism that can stably support a display screen on a base and that can position the display screen at a selected inclined angular position.

Another object of the present invention is to provide an electronic device having a supporting mechanism. The supporting mechanism can stably support a display screen on a base, and can position the display screen at a selected inclined angular position.

The purpose of the present invention and the solution to the conventional technical problems are achieved through employment of the below technical means. According to one aspect of disclosure of the present invention, a supporting mechanism for supporting a display screen on a base comprises a connecting plate, a hinged plate, and a supporting element. The connecting plate is adapted to be disposed on the display screen, and includes a first hinged element. The hinged plate is hinged to and rotatable about the first hinged element, and includes a second hinged element. The supporting element has a first end hinged to and rotatable about the second hinged element, and a second end opposite to the first end and adapted to be engageable with the base to support the display screen on the base.

According to another aspect of this invention, an electronic device comprises a base, a display screen connected rotatably to one end of the base, and a supporting mechanism including a connecting plate, at least one hinged plate, and at least one supporting element. The connecting plate is disposed on the display screen, and includes at least one first hinged element. The hinged plate is hinged to and rotatable about the first hinged element, and includes a second hinged element. The supporting element has a first end hinged to and rotatable about the second hinged element, and a second end opposite to the first end and engageable with the base to support the display screen on the base.

According to still another aspect of this invention, an electronic device comprises a display screen and a supporting mechanism including a connecting plate, a hinged plate, and a supporting element. The connecting plate is disposed on the display screen, and includes a first hinged element. The hinged plate is hinged to and rotatable about the first hinged element, and includes a second hinged element. The supporting element has a first end hinged to and rotatable about the second hinged element.

Through the aforesaid technical means, the advantages and effectiveness of the electronic device having the supporting mechanism according to the present invention reside in the fact that through the hinged plate being rotatable relative to the connecting plate about the first hinged element, and through the supporting element being rotatable relative to the hinged plate about the second hinged element, each supporting element can be adjusted to engage the base, so that the display screen can be stably supported by the supporting elements on the base at an inclined angular position and can be selectively adjusted to a desired inclination angle.

### BRIEF DESCRIPTION OF THE DRAWINGS

Other features and advantages of the present invention will become apparent in the following detailed description of the embodiments of the invention, with reference to the accompanying drawings, in which:

FIG. 1 is a perspective view of an electronic device having a supporting mechanism according to the first embodiment of the present invention;

FIG. 2 is a partially exploded perspective view of the first embodiment;

FIG. 3 is a fragmentary exploded perspective view of the first embodiment taken from another angle;

FIG. 4 is an exploded perspective view of the supporting mechanism of the first embodiment;

FIG. 5 is a fragmentary enlarged perspective view of the first embodiment;

FIG. 6 is a fragmentary enlarged perspective view of a cover plate of the first embodiment;

FIG. 7 is a view similar to FIG. 1, but illustrating the cover plate being moved downward;

FIG. 8 is a perspective view of the supporting mechanism of the first embodiment in an assembled state;

FIG. 9 is a perspective view of the first embodiment, illustrating supporting elements of the supporting mechanism being moved away from a receiving groove in a display screen of the electronic device;

FIG. 10 is a perspective view of the first embodiment, illustrating the supporting elements disposed in a use position and engaged with a base of the electronic device;

FIG. 11 is a perspective view of an electronic device having a supporting mechanism according to the second embodiment of the present invention in a use position; and

FIG. 12 is a perspective view of an electronic device having a supporting mechanism according to the third embodiment of the present invention in a use position.

### DETAILED DESCRIPTION OF THE PREFERRED EMBODIMENTS

The above-mentioned and other technical contents, features, and effects of this invention will be clearly presented from the following detailed description of the three embodiments in coordination with the reference drawings. Through description of the concrete implementation method, the technical means employed and the effectiveness to achieve the predetermined purposes of the present invention will be thoroughly and concretely understood. However, the enclosed drawings are used for reference and description only, and are not used for limiting the present invention.

Before this invention is described in detail, it should be noted that, in the following description, similar elements are designated by the same reference numerals.

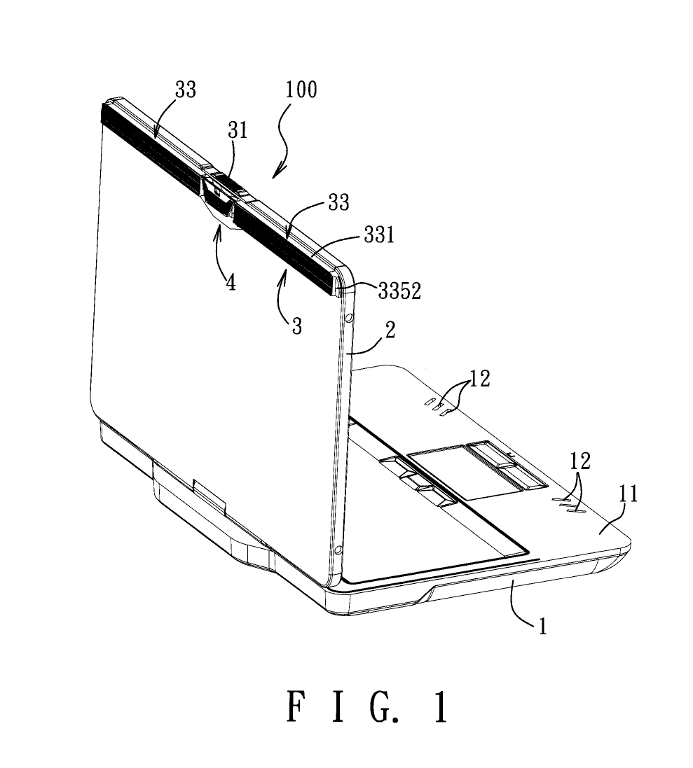

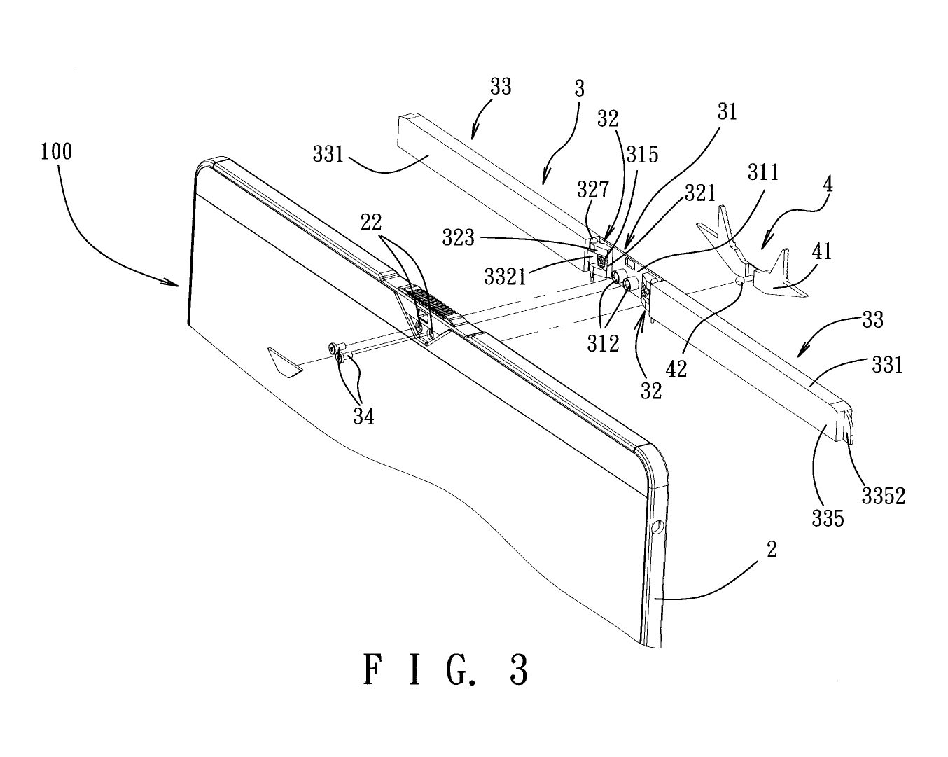

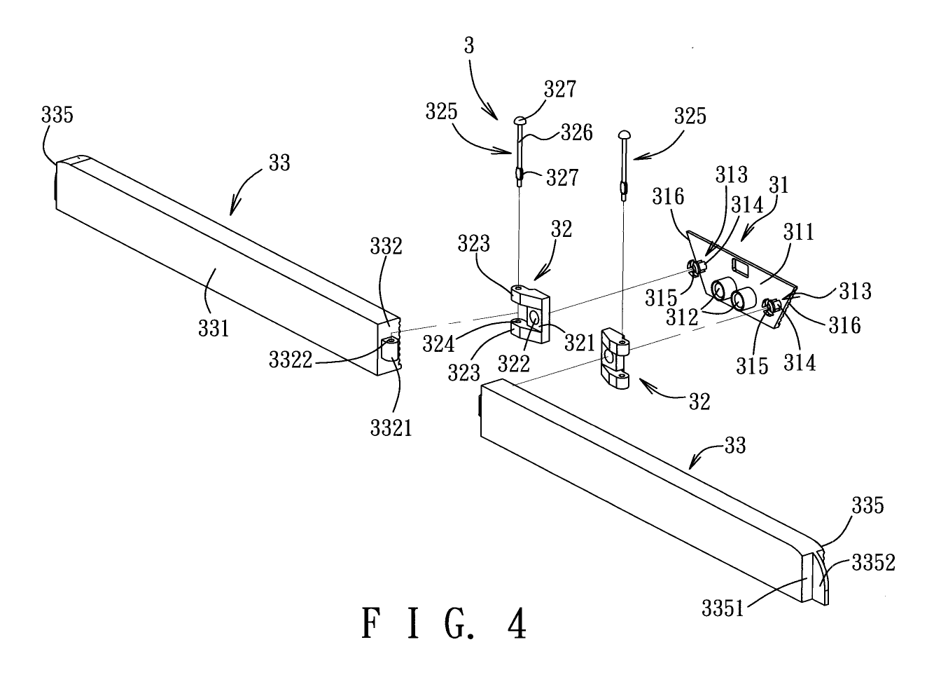

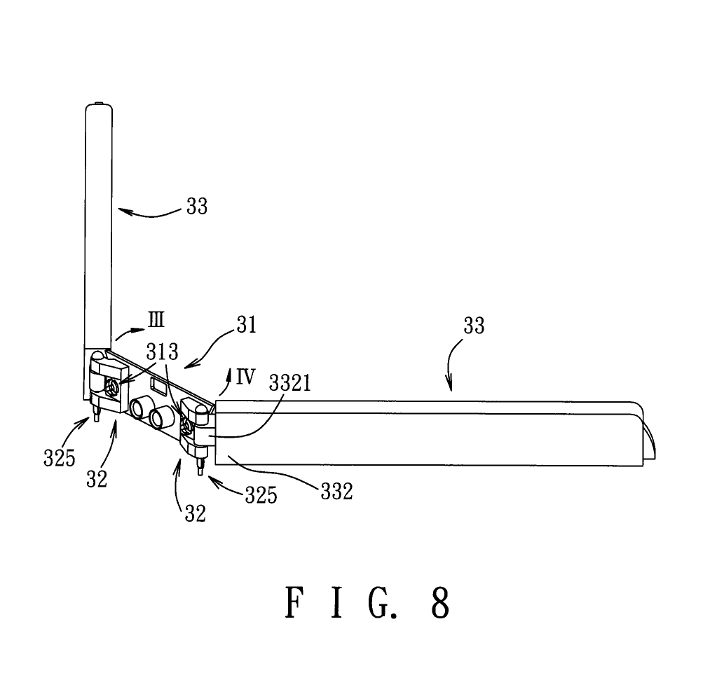

Referring to FIGS. 1 to 10, an electronic device 100 according to the first embodiment of the present invention is exemplified as a notebook computer, and is shown to comprise a base 1, a display screen 2 connected rotatably to one end of the base 1, and a supporting mechanism 3.

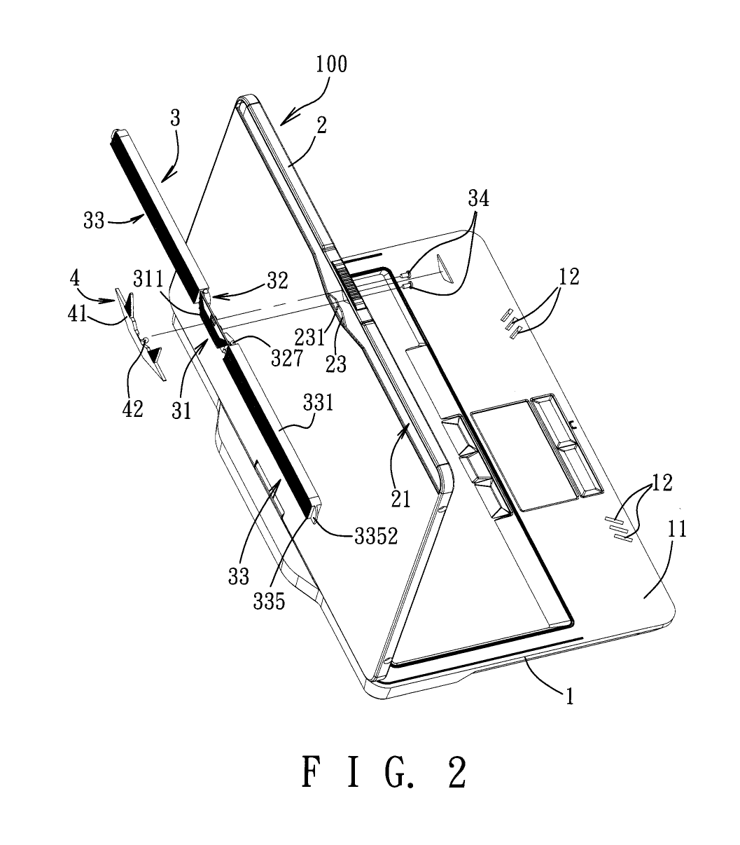

With reference to FIGS. 2 to 4, the display screen 2 is formed with a receiving groove 21 at a rear face thereof for receiving the supporting mechanism 3. In this embodiment, the supporting mechanism 3 includes a connecting plate 31, two hinged plates 32, and two supporting elements 33. The connecting plate 31 includes a plate body 311, and two spaced-apart studs 312 projecting from a front face of the plate body 311. The two studs 312 correspond in position to two through holes 22 that are formed in the display screen 2 and that communicate spatially with the receiving groove 21. Two screws 34 are respectively inserted through the through holes 22, and are engaged threadedly to the studs 312, so that the connecting plate 31 is fixed to the display screen 2. The fixing of the connecting plate 31 to the display screen 2 is not limited to the aforesaid disclosure. The connecting plate 31 may be fixed to the display screen 2 through a hook-engaging method. The connecting plate 31 further includes two first hinged elements 313 spaced apart in a left-right direction and projecting from the front face of the plate body 311. Each first hinged element 313 is spaced apart from and disposed outward of a respective stud 312 for connection with a respective hinged plate 32. Each first hinged element 313 includes a plurality of annularly arranged radially compressible resilient arms 314. Each resilient arm 314 extends in a front-rear direction.

In this embodiment, each hinged plate 32 includes a plate body 321 formed with a through hole 322 extending in a front-rear direction. The resilient arms 314 of each first hinged element 313 extend resiliently through the through hole 322 in a corresponding hinged plate 32. When front ends 315 of the resilient arms 314 extend out of the through hole 322 in the corresponding hinged plate 32, due to restoring forces of the resilient arms 314, the front ends 315 of the resilient arms 314 are retained on a front face of the plate body 321 of the corresponding hinged plate 32. Through this configuration, during assembly, each hinged plate 32 can be quickly and easily assembled on the respective first hinged element 313. Further, each hinged plate 32 can rotate relative to the connecting plate 31 about the respective first hinged element 313. Each hinged plate 32 further includes two extension arms 323 extending respectively from top and bottom ends of the plate body 321 in the left-right direction.

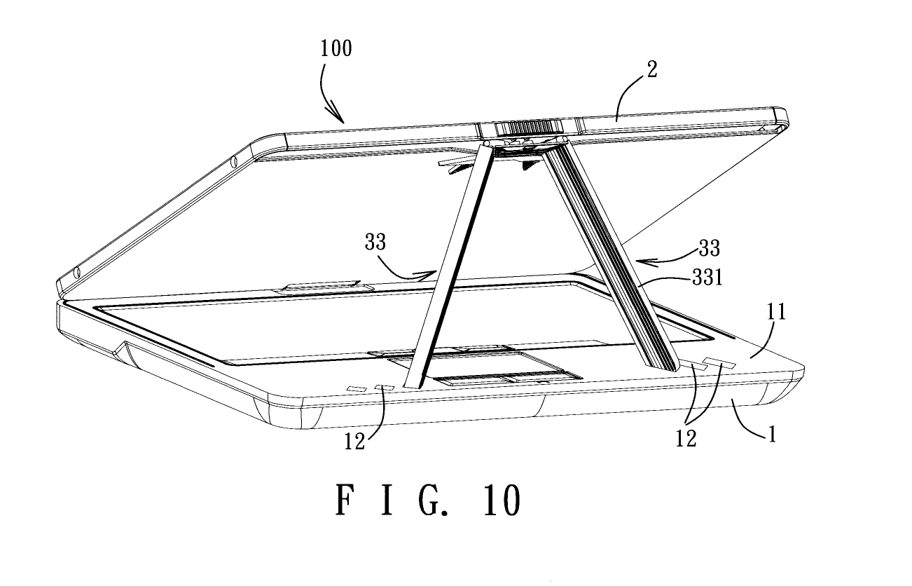

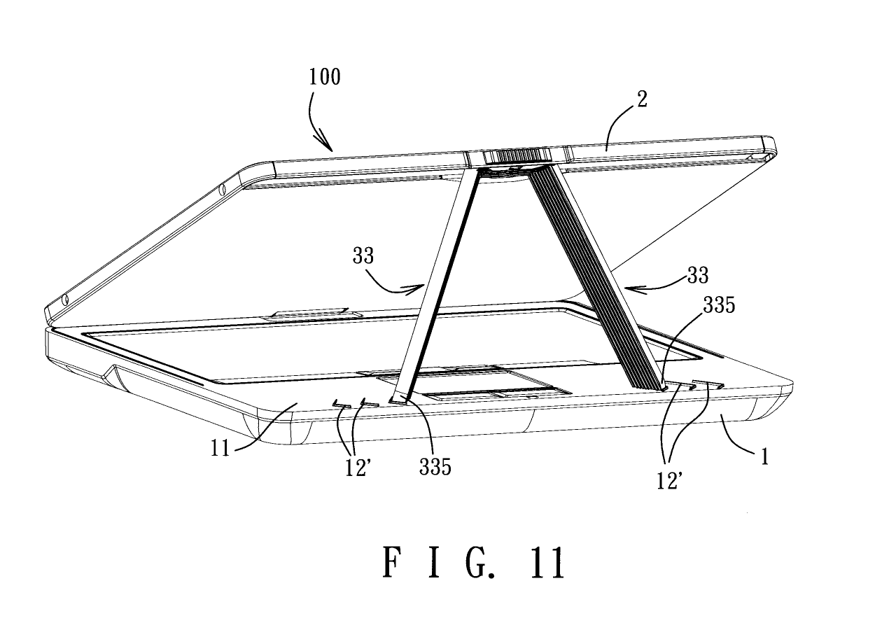

The supporting elements 33 are disposed movably in the receiving groove 21 between a non-use position, as shown in FIG. 1, and a use position, as shown in FIG. 10. In the non-use position, the supporting elements 33 are stored in the receiving groove 21. In the use position, the supporting elements 33 are pivoted away from the receiving groove 21 to engage with the base 1. Each supporting element 33 includes a plate body 331 having a first end 332, and a second end 335 opposite to the first end 332. The first end 332 has a connecting portion 3321 projecting therefrom and disposed between the extension arms 323 of the respective hinged plate 32. Each hinged plate 32 further includes a second hinged element 325 interconnecting pivotally the extension arms 323 and the connecting portion 332, so that the supporting element 33 can pivot relative to the respective hinged plate 32 about the second hinged element 325. In this embodiment, the connecting portion 332 of each supporting element 33 defines a connecting hole 333 extending in a top-bottom direction. Each extension arm 323 is formed with a passage hole 324 extending in the top-bottom direction and aligned with the connecting hole 333. The second hinged element 325 includes a shaft 326 extending through the connecting hole 333 in the respective supporting element 33 and the passage holes 324 in the extension arms 323, and two stop portions 327 disposed respectively on two opposite ends of the shaft 326 and spaced apart in the top-bottom direction. The stop portions 327 abut respectively against outer ends of the extension arms 323, so that the shaft 326 of the second hinged element 325 can be stably positioned and cannot be easily detached from the connecting hole 333 of the respective supporting element 33 and the passage holes 324 in the extension arms 323. Further, since an axis of the first hinged element 313 is perpendicular to an axis of the second hinged element 325, because each hinged plate 32 is rotatable relative to the connecting plate 31 about the first hinged element 313, and because each supporting element 33 is rotatable relative to the respective hinged plate 32 about the second hinged element 325, each supporting element 33 can be pivoted simultaneously about the two perpendicular axes, and can be moved between the non-use position (see FIG. 1) and the use position (see FIG. 10).

Because the hinged plates 32 and the supporting elements 33 are connected to the front face of the plate body 311 of the connecting plate 31, to prevent each supporting element 33 from bumping against the plate body 311 during rotation about the respective second hinged element 325, left and right ends of the plate body 311 are respectively formed with a slanting edge 316. The slanting edge 316 is proximate to the respective first hinged element 313, and slants inwardly from a top-to-bottom direction. Through this configuration, a space is formed between the first end 332 of each supporting element 33 and a respective one of the left and right ends of the plate body 311.

The electronic device 100 further comprises a cover plate 4 which includes a plate body 41, and a connecting rod 42 projecting forward from the plate body 41 and engaged with an aperture 231 formed in a connecting plate 23 at the rear face of the display screen 2. Through this configuration, the plate body 41 is movable relative to the connecting plate in a front-rear direction, and is rotatable relative to the same. The plate body 41 covers a partially exposed portion of the receiving groove 21 to prevent the receiving groove 21 from accumulating dust.

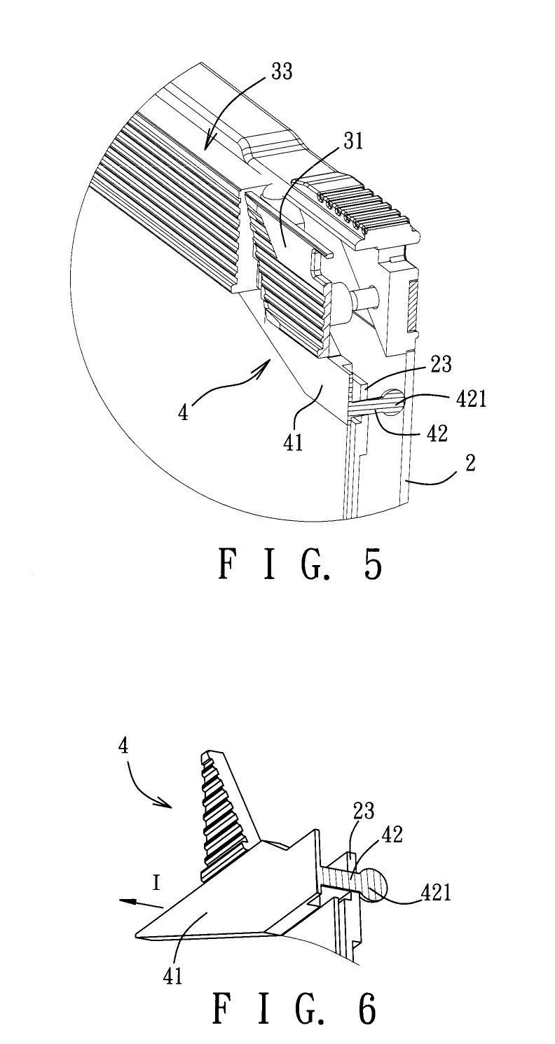

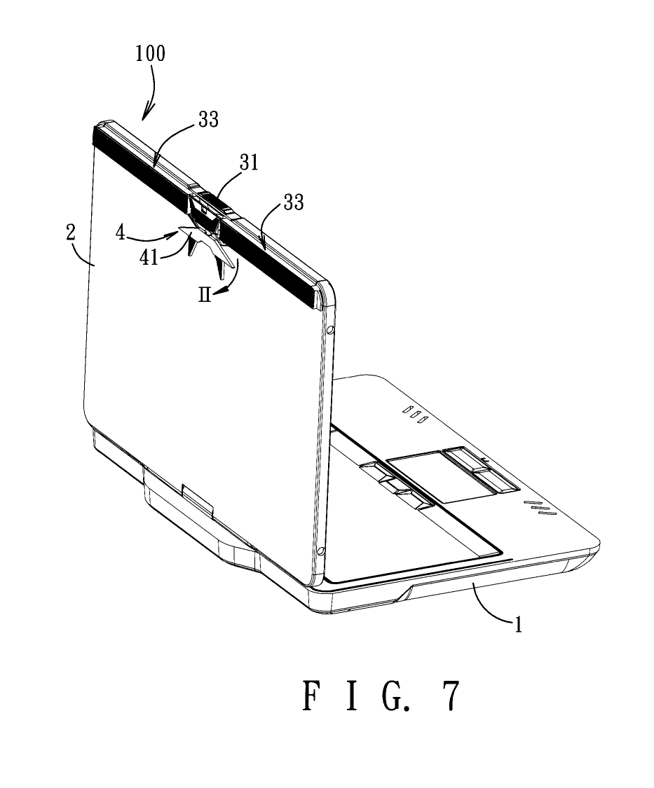

With reference to FIGS. 5 to 7, when the electronic device 100 is in an operational mode, as shown in FIG. 1, the plate body 41 of the cover plate 4 is moved rearward in the direction of an arrow (I) until a stop portion 421 of the connecting rod 42 abuts against a front face of the connecting plate 23, after which the plate body 41 is rotated in the direction of an arrow (II) or an opposite direction of the arrow (II) to be disposed in an inverted position, as shown in FIG. 7.

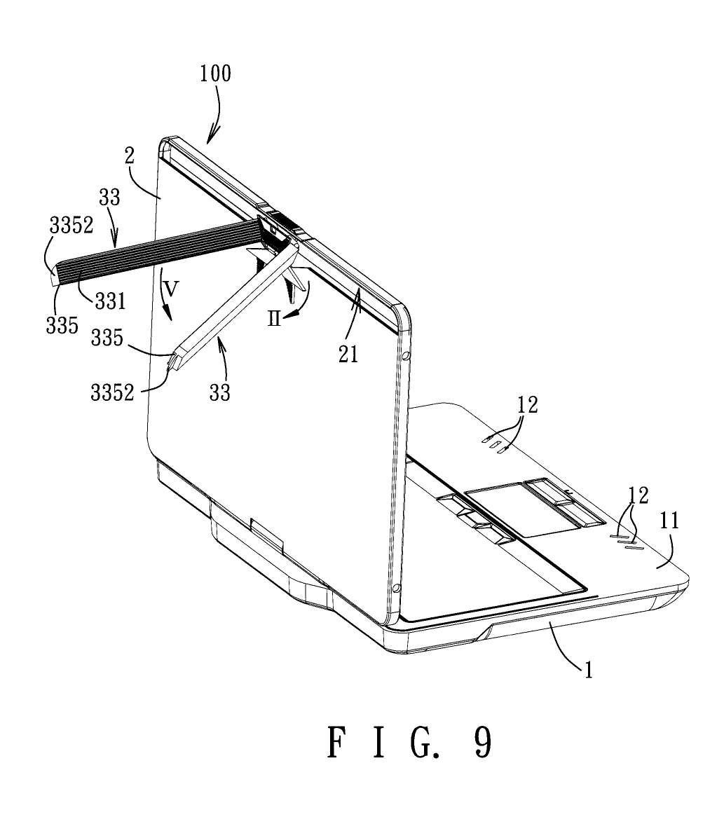

With reference to FIGS. 7 to 9, the second ends 335 of the supporting elements 33 are pulled and pivoted away from the receiving groove 21. The supporting elements 33 respectively pivot in the direction of arrows (III) and (IV) relative to the hinged plates 32 about the respective second hinged elements 325. Simultaneously, the supporting elements 33 are moved in the direction of the arrows (II) and (V), respectively, to rotate relative to the connecting plate 31 about the respective first hinged elements 313. Hence, the supporting elements 33 are moved from the non-use position shown in FIG. 7 to a position shown in FIG. 9.

With reference to FIG. 9, the second ends 335 of the supporting elements 33 are engageable with the base 1 to support the display screen 2 on the base 1. Preferably, the base 1 includes a top wall 11, and a plurality of spaced-apart limiting portions 12 provided on the top wall 11. The second end 335 of each supporting element 33 can be engaged selectively with one of the limiting portions 12. Through this configuration, the display screen 2 can be stably supported by the supporting elements 33 on the base 1 at an inclined angular position. In this embodiment, each limiting portion 12 is configured as a limiting engaging groove. The second end 335 of each supporting element 33 has an end face 3351 abuttable against the top wall 11, and an engaging piece 3352 projecting from the end face 3351 and engageable with a selected one of the limiting portions or limiting engaging grooves 12. It should be noted that an included angle between the display screen 2 and the top wall 11 of the base 1 depends on the lengths of the supporting elements 33 and the position of the limiting portions 12. The number of the limiting portions 12 or the length of the supporting element 33 can be altered according to the requirement.

With reference to FIGS. 9 and 10, to place the supporting elements 33 at the use position shown in FIG. 10, the display screen 2 is first rotated relative to the base 1, after which the display screen 2 is moved downward. By abutting the end face 3351 of the second end 335 of each supporting element 33 against the top wall 11, and by engaging the engaging piece 335 of each supporting element 33 with a selected one of the limiting engaging grooves 12, the display screen 2 can be stably supported on the base 1 by the supporting elements 33 at an inclined angular position and will not rotate relative to the base 1. Further, to adjust an inclination angle of the display screen 2 relative to the base 1, the display screen 2 is first moved upward to disengage the engaging pieces 335 of the supporting elements 33 from the respective limiting engaging grooves 12, after which the engaging piece 335 of each supporting element 33 is brought to align with another one of the limiting engaging grooves 12. The display screen 2 is then moved downward to engage the engaging piece 335 with the limiting engaging groove 12.

It should be noted that the number of each of the first hinged element 313, the hinged plate 32, and the supporting element 33 is not limited to the aforesaid disclosures, and there may only be one first hinged element 313, one hinged plate 32, and one supporting element 33.

Referring to FIG. 11, an electronic device 100 according to the second embodiment of the present invention is shown to be similar to the first embodiment. However, in this embodiment, each limiting portion 12′ is configured as a ridge that projects upwardly from the top wall 11 of the base 1 and that has a substantially L-shaped cross section. The second end 335 of each supporting element 33 abuts against the top wall 11 and a selected one of the limiting portions or ridges 12′. Through this configuration, the display screen 2 can be stably supported by the supporting elements 33 on the base 1 at an inclined angular position.

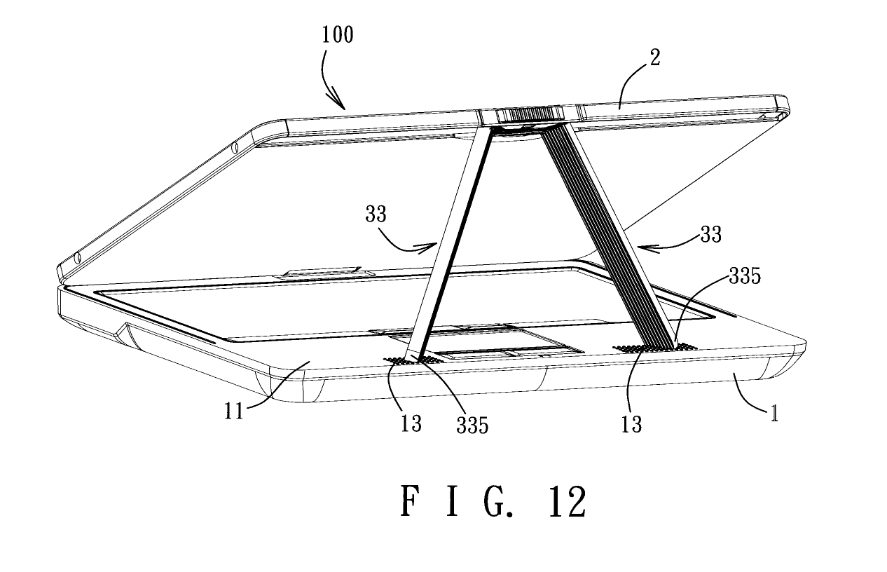

Referring to FIG. 12, an electronic device 100 according to the third embodiment of the present invention is shown to be similar to the first embodiment. However, in this embodiment, the base 1 includes two spaced-apart rough surfaces 13 formed on the top wall 11. The second end 335 of each supporting element 33 abuts against a respective rough surface 13. Through the interference friction between the second ends 335 of the supporting elements 33 and the respective rough surfaces 13, the display screen 2 can be stably supported by the supporting elements 33 on the base 1 at an inclined angular position.

From the aforesaid description, because each hinged plate 32 is rotatable relative to the connecting plate 31 about the respective first hinged element 313, and because each supporting element 33 is rotatable relative to the hinged plate 32 about the respective second hinged element 325, each supporting element 33 can be adjustably and selectively engaged with the limiting portions 12, 12′ of the base 1, so that the display screen 2 of the electronic equipment 100 in each embodiment can be stably supported by the supporting elements 33 on the base 1 at an inclined angular position. Further, an inclination angle of the display screen 2 relative to the base 1 can also be adjusted accordingly. Hence, the objects of the present invention can be realized.

While the present invention has been described in connection with what are considered the most practical and embodiments, it is understood that this invention is no limited to the disclosed embodiments but is intended to cover various arrangements included within the spirit and scope of the broadest interpretations and equivalent arrangements.

I claim:

1. A supporting mechanism for supporting a display screen on a base, comprising:
a connecting plate adapted to be disposed on the display screen and including a first hinged element;
a hinged plate hinged to and rotatable about said first hinged element, and including a second hinged element; and
a supporting element having a first end hinged to and rotatable about said second hinged element, and a second end opposite to said first end and adapted to be engageable with the base to support the display screen on the base.

2. The supporting mechanism of claim 1, wherein said hinged plate further includes two spaced-apart extension arms, said first end of said supporting element having a connecting portion disposed between said extension arms, said second hinged element connecting pivotally said extension arms and said connecting portion.

3. The supporting mechanism of claim 2, wherein said connecting portion defines a connecting hole, each of said extension arms being formed with a passage hole aligned with said connecting hole, said second hinged element including a shaft extending through said connecting hole and said passage holes of said extension arms, and two spaced-apart stop portions disposed on and projecting radially from said shaft, said stop portions abutting respectively against outer sides of said extension arms.

4. The supporting mechanism of claim 2, wherein said hinged plate further includes a plate body formed between said extension arms and having a through hole, said first hinged element including a plurality of annularly arranged radially compressible resilient arms extending resiliently through said through hole and retained on said plate body.

5. The supporting mechanism of claim 4, wherein said connecting plate has a slanting edge proximate to said first hinged element.

6. The supporting mechanism of claim 1, wherein said first hinged element has an axis perpendicular to that of said second hinged element.

7. An electronic device comprising:
a base;
a display screen connected rotatably to one end of said base; and
a supporting mechanism including
a connecting plate disposed on said display screen and including at least one first hinged element;
at least one hinged plate hinged to and rotatable about said first hinged element, and including a second hinged element; and
at least one supporting element having a first end hinged to and rotatable about said second hinged element, and a second end opposite to said first end and engageable with said base to support said display screen on said base.

8. The electronic device of claim 7, wherein said display screen is formed with a receiving groove, said supporting element being disposed movably in said receiving groove between a non-use position and a use position, wherein, in said use position, said supporting element is pivoted away from said receiving groove to engage with said base.

9. The electronic device of claim 8, wherein said base includes a top wall, and a plurality of spaced-apart limiting portions provided on said top wall, said second end of said supporting element being selectively engaged with one of said limiting portions.

10. The electronic device of claim 9, wherein said limiting portions are configured as limiting engaging grooves, said second end of said supporting element having an end face abutting against said top wall, and an engaging piece projecting from said end face and engaged with a selected one of said limiting engaging grooves when said supporting element is in said use position.

11. The electronic device of claim 9, wherein said limiting portions are configured as limiting ridges, said second end of said supporting element abutting against said top wall and a selected one of said limiting ridges when said supporting element is in said use position.

12. The electronic device of claim 8, wherein said base includes a top wall, and a rough surface formed on said top wall, said second end of said supporting element abutting against said rough surface when said supporting element is in said use position.

13. The electronic device of claim 8, wherein said hinged plate further includes two spaced-apart extension arms, said first end of said supporting element having a connecting portion disposed between said extension arms, said second hinged element connecting pivotally said extension arms and said connecting portion.

14. The electronic device of claim 13, wherein said connecting portion defines a connecting hole, each of said extension arms being formed with a passage hole aligned with said connecting hole, said second hinged element including a shaft extending through said connecting hole and said passage holes of said extension arms, and two spaced-apart stop portions disposed on and projecting radially from said shaft, said stop portions abutting respectively against outer sides of said extension arms.

15. The electronic device of claim 13, wherein said hinged plate further includes a plate body formed between said extension arms and having a through hole, said first hinged element including a plurality of annularly arranged radially compressible resilient arms extending resiliently through said through hole and retained on said plate body.

16. The electronic device of claim 15, wherein said connecting plate has a slanting edge proximate to said first hinged element.

17. The electronic device of claim 7, wherein said first hinged element has an axis perpendicular to that of said second hinged element.

18. The electronic device of claim 7, wherein said connecting plate includes two said first hinged elements spaced apart from each other, said supporting mechanism including two said hinged plates and two said supporting elements, each of said hinged plates being hinged to and rotatable about a respective one of said first hinged elements, said first end of each of said supporting elements being hinged to and rotatable about said second hinged element of a respective one of said hinged plates, said second ends of said supporting elements being engageable with said base.

19. An electronic device comprising:
a display screen; and
a supporting mechanism including
a connecting plate disposed on said display screen and including a first hinged element;
a hinged plate hinged to and rotatable about said first hinged element, and including a second hinged element; and
a supporting element having a first end hinged to and rotatable about said second hinged element.
